(19) United States
(12) Patent Application Publication
(10) Pub. No.: US 2021/0249316 A1
(43) Pub. Date: Aug. 12, 2021

(54) METHODS AND SYSTEM OF IMPROVING CONNECTIVITY OF INTEGRATED COMPONENTS EMBEDDED IN A HOST STRUCTURE

(71) Applicant: Nano Dimension Technologies LTD., Nes Ziona (IL)

(72) Inventor: Jaim Nulman, Santa Clara, CA (US)

(21) Appl. No.: 17/260,714

(22) PCT Filed: Jul. 17, 2019
(86) PCT No.: PCT/US19/42213

§ 371 Date: Jan. 15, 2021

Related U.S. Application Data
(60) Provisional application No. 62/698,414, filed on Jul. 16, 2018.

(51) Int. Cl. H01L 21/66; H01L 21/67; H01L 21/48

(52) U.S. Cl. CPC H01L 22/20; B33Y 10/00; H01L 21/4867; H01L 21/67253

(57) ABSTRACT

The disclosure relates to systems, and methods for improving connectivity of embedded components. Specifically, the disclosure relates to systems and methods for using additive manufacturing to improve connectivity of embedded components with the host structure and/or other embedded components by selectably bridging the gap naturally formed due to manufacturing variation and built in tolerances, between the embedded components or devices and the host structure, and between one embedded component and a plurality of other embedded components.

### BACKGROUND

The disclosure is directed to systems, and methods for improving connectivity of embedded components. Specifically, the disclosure is directed to systems and methods for using additive manufacturing to improve connectivity of embedded components with the host structure and/or other embedded components by selectably bridging the gap formed between the embedded device or devices and the host structure, and between one embedded device and a plurality of other embedded devices.

Additive manufacturing offers an opportunity to produce mechanical components that include composite materials, furthermore with the availability of conductive materials in the additive manufacturing industry, there is a need to embed components made by third parties into the structure being manufactured. These conductive materials could be electrical, thermal, acoustic, and/or optical.

For example, state-of-the-art Chip embedding technology has become a necessity in the fabrication of complex electronics. New applications with embedded sensors, driven by miniaturization and optimized packages for the different demands for the sensors—became urgent; as did an increase of complexity by embedding of chips with large number of interconnections and more.

Given the mass-production methods of manufacturing and the resulting size variability of the final products, both the embedded components (e.g., IC 200) and the slots or sites for their embedding, there will always exist a gap between the walls of the embedding site and the component being embedded. This gap requires sealing in order to prevent the embedded component from becoming loose, or if special structures such as electrical interconnect wires, thermal dissipation wires, fiber optics, or mechanical transducing wires are required to go from the box encapsulating the embedded component to the embedded component; a support in the gap is required, otherwise the wire being deposited by additive manufacturing might have a break or be very thin resulting in lack of desired functionality, for example in the case of integrated circuits or electronic sensors, this could result in loss of conductivity or a very high resistance due to the reduced metal thickness (See e.g., FIGS. 3C, 3D).

The present disclosure is directed toward overcoming one or more of the above-identified problems.

### SUMMARY

Disclosed, in various embodiments, are systems, and methods for using additive manufacturing to improve thermal, electrical, optical, acoustic, and mechanical connectivity of embedded components with the host structure and/or other integrated circuits by bridging the gap formed between the embedded components and the host structure. The embedded component could be, for example, a micro switch, a sensor, a piezo-electric material, a lens, an integrated circuit, a light emitting diode, and the like or their combination that somehow need connectivity, either electrical, acoustical, optical, thermal, mechanical and the like.

In an embodiment provided herein is a method for increasing connectivity of embedded components in a host structure implementable in an additive manufacturing systems, comprising: providing the host structure with a top surface comprising a well having a well wall and a well floor configured to receive and accommodate a first embedded component (e.g., IC); positioning a first component to be embedded having an apical surface, a basal surface and a perimeter within the well, thereby embedding the first component; inspecting the first embedded component; determining the gap between the well wall and the perimeter of the first embedded component: and if the gap between the well wall and the perimeter of the embedded component is above a predetermined gap threshold yet smaller than a bridging threshold, using the additive manufacturing system, adding a bridging member between the perimeter of the embedded component and the top surface of the host structure adjacent to the well wall.

In another embodiment, the additive manufacturing system further comprises: a processing chamber; at least one of an optical module, a mechanical module, and an acoustic module; wherein the at least one of optical module, mechanical module, and the acoustic module comprise a processor in communication with a non-volatile memory including a processor-readable media having thereon a set of executable instructions, configured to, when executed, cause the processor to: capture an image of the host structure with the first embedded component; measure the gap between the well wall and the perimeter of the first embedded component; compare the measured gap to the predetermined gap threshold; compare the measured gap to the bridging threshold; if the measured gap is greater than the gap threshold yet smaller than the bridging threshold, instruct at least one of the operator and the additive manufacturing system to add a bridging member between the perimeter wall of the first embedded component and the top surface of the host structure adjacent to the well wall; else if the measured gap is smaller than the gap threshold, prevent the additive manufacturing system from adding a bridging member between the perimeter of the first embedded component and the top surface of the host structure adjacent to the well wall; else if the measured gap is greater than the gap threshold and greater than the bridging threshold, actuate an alarm.

In yet another embodiment, provided herein is a processor readable media having thereon a set of executable instructions, configured to, when executed, cause a processor to: capture an image of a host structure with a top surface comprising a well having a well wall and a well floor configured to receive and accommodate a first component to be embedded, wherein the first component to be embedded has an apical surface, a basal surface and a perimeter; using at least one of an optical module, and acoustic module, and a mechanical module, measure a gap between the well wall of the host structure and the perimeter of the first embedded component; compare the measured gap to a predetermined gap threshold; compare the measured gap to a bridging threshold; if the measured gap is greater than the gap threshold and smaller than the bridging threshold, instruct at least one of the operator and the additive manufacturing system to add a bridging member between the perimeter of the first embedded component and the top surface of the host structure adjacent to the well wall; else if the measured gap is smaller than the gap threshold, prevent the additive manufacturing system from adding the bridging member between the perimeter of the embedded component and the top surface of the host structure adjacent to the well wall; else if the measured gap is greater than the gap threshold and greater than the bridging threshold, actuate an alarm.

These and other features of the systems, and methods for using additive manufacturing systems to improve connectivity of embedded components with the host structure and/or other embedded components by bridging the gap formed between the embedded components and the host structure, will become apparent from the following detailed description when read in conjunction with the figures and examples, which are exemplary, not limiting.

### BRIEF DESCRIPTION OF THE FIGURES

For a better understanding of the systems, and methods for improving connectivity of embedded integrated circuits, with regard to the embodiments thereof, reference is made to the accompanying examples and figures, in which:

FIG. 1A is an isometric view of an embedded integrated circuit in a host structure's well, with top plan view illustrated in FIG. 1B and a X-Z cross section along line A-A of FIG. 1A illustrated in FIG. 1C;

FIG. 2 is a schematic illustrating an embodiment of the host structure comprising a plurality of different embedded components;

FIG. 3A illustrates an enlarged top plan view of FIG. 1B with contact pads as produced currently, with X-Z cross section along line B-B of FIG. 3A illustrated in FIG. 3B, top plan view as in FIG. 3A with current electrical connection to the contact pads illustrated in FIG. 3C and the resulting break in X-Z cross section along line C-C of FIG. 3C illustrated in FIG. 3D;

FIG. 4, is a schematic illustration, from left to right of the impact of various measured gaps on bridging deposition;

FIG. 5, is a schematic illustration of potential resulting gaps and bridging deposition of a quadrilateral IC in a quadrilateral well using the methods and systems disclosed and claimed herein;

FIG. 6A, is a top plane (X-Y) view schematic illustration of the implementation of the methods described for deposition of contact layer (insulating or conductive) over bridging member(s) added using the systems described, with a side (X-Z) elevation view thereof illustrated in FIG. 6B;

and

FIG. 7, is a flowchart describing an embodiment of the methods described herein.

### DETAILED DESCRIPTION

Provided herein are embodiments of systems and methods for using additive manufacturing to improve connectivity of embedded components and integrated circuits with the host structure and/or other embedded components by bridging the gap formed between the embedded components and the host structure and/or other embedded and other components.

Technologies for the embedding of active and passive components into host structures have become a necessity for the development of complex electronics. Different embedding technologies have been developed due to different requirements with respect to electrical performance, chip dimensions, and interconnection(s).

Likewise, the need to place component inside other hosts for the purposes of isolating and/or insulating that component from the environment, for example, assembly of micro LEDs in unique structures, etc., can be achieved using additive manufacturing for embedding such devices. Most if not all embedded devices require some kind of connectivity outside the embedded component 200, so additional material is deposited for this purpose. Due to manufacturing tolerances of the devices (interchangeable with “components”, “circuits”, “chips”, “integrated circuits”) to be embedded as well as the host structure (interchangeable with printed circuit board (PCB), flexible printed circuits (FPC) and high-density interconnect printed circuits (HDIPC)), the gap between them could limit the mechanical, electrical, and optical if any, properties of the connectivity material. Accordingly, the methods and systems provided herein improve the mechanical, electrical, thermal, acoustical, and optical connectivity of embedded components to their host structure. As disclosed, the embedded component could be a micro switch, a sensor, a piezo-electric material, a diamond, an integrated circuit, a light emitting diode, a laser, and the like, that somehow need connectivity, either electrical, acoustic, optical, thermal, mechanical, their combination and the like. As used herein, the term “connectivity” in the context of the disclosed technology, refers to the certainty of electrical and physical connection between the wiring pattern of the host and the embedded component. In another embodiment, the term refers to the reciprocal of the resistivity to flow of electrons, sound, photons, heat, strain, etc., which connectivity is sought to improve when compared to the same configuration without implementing the disclosed methods and systems disclosed.

The disclosure provides for methods for bridging the gap (e.g., between the embedded component and the host), when necessary, thus resulting in an embedded device in a structure manufactured using additive manufacturing to be held in place and/or the ability to add other materials that go from the embedded device to the structure without any mechanical and electrical defects.

Three-dimensional (3D) printing, as an embodiment of additive manufacturing, has been used to create static objects and other stable structures, such as prototypes, products, and molds. Three dimensional printers can convert a 3D image, which is typically created with computer-aided design (CAD) software, into a 3D object through the layer-wise addition of material. For this reason, 3D printing has become relatively synonymous with the term “additive manufacturing.” In contrast, “subtractive manufacturing” refers to creating an object by etching, cutting, milling, or machining away material to create a desired shape and include plasma chambers, wet chemical benches, CNC machining like lathers, mills, grinders, and routers.

The systems used can typically comprise several sub-systems and modules. These can be, for example: a mechanical sub-system to control the movement of the additive manufacturing elements such as lasers or print heads as an example; the substrate (or chuck) its heating and conveyor motions; the ink composition injection systems, the material filament source, or the liquid source of material; the curing/sintering sub-systems; a computer based sub-system that controls the process and generates the appropriate additive manufacturing instructions; a component placement system (e.g., robotic arms for “pick-and-place”); machine vision system; a coordinates and dimensions measurement system, and a command and control system to control the additive manufacturing process.

Accordingly and in an embodiment, provided herein is a method for increasing connectivity of embedded components in a host structure, implementable in an additive manufacturing system comprising: providing the host structure with a top surface comprising a well having a well wall and a well floor configured to receive and accommodate a first embedded component; positioning the first embedded component having an apical surface, a basal surface and a perimeter within the well, thereby embedding the first component; inspecting the first embedded component; determining the gap between the well wall and the perimeter of the first embedded component: and if the gap between the well wall and the perimeter of the embedded component is above a predetermined gap threshold yet smaller than a bridging threshold, using the additive manufacturing system, adding a bridging member between the perimeter of the embedded component and the top surface of the host structure adjacent to the well wall.

The term component can refer, as an example, to “integrated circuit” or “chip” such as a packaged or unpacked, singulated, IC device. The term “chip package” may particularly denote a housing that chips come in for plugging into (socket mount) or soldering onto (surface mount) a host structure such as a printed circuit board (PCB), thus creating a mounting for a chip. In electronics, the term chip package or chip carrier may denote the material added around a component or integrated circuit to allow it to be handled without damage and incorporated into a circuit.

Furthermore, the IC or chip package used in conjunction with the systems, and methods described herein can be Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Ball-Grid Array (BGA), a Quad Flat No-Lead (QFN) package, a Land Grid Array (LGA) package, a passive component, or a combination comprising two or more of the foregoing.

In another embodiment, embedded components can be other elements sought to be added to the host structure and can vary widely, for example weighting elements such as Led structures, finished elements such as vibration isolators, fans, complex heat sinks, lenses, power sources, liquid-containing vessels, and the like. The term “component” does not intend to limit the type of component or device embedded and is intended to encompass anything to be incorporated into the host structure in a pre-fabricated site within the host structure, sized and configured to accommodate that component/device.

As indicated, the systems used to implement the methods for fabricating host structures including embedded components with improved connectivity can have additional conducting materials deposited or otherwise added thereon, which may contain different metals. For example, a Silver (Ag) Copper, or Gold. Likewise, other metals (e.g., Al, Ni, Pt) or metal precursors can also be used and the examples provided should not be considered as limiting.

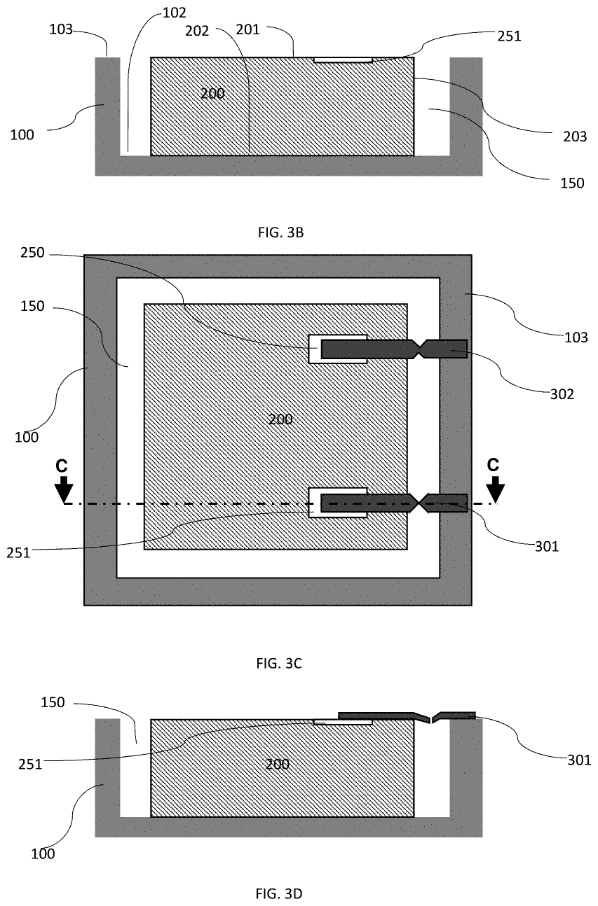

In certain embodiments, the additive manufacturing systems provided herein further comprise a robotic arm in communication with the CAM module and under the control of the CAM module, configured to place each of the plurality of chips in its predetermined well. The robotic arm can be further configured to operatively couple and connect the chip to the contact pad (see e.g., 250, FIG. 3A).

Furthermore, the systems for forming a host structure with improved connectivity further comprises: a processing chamber; at least one of an optical module, a mechanical module, and an acoustic module; wherein the at least one of optical module, mechanical module, and the acoustic module comprise a processor in communication with a non-volatile memory (or non-volatile storage device) including a processor-readable media having thereon a set of executable instructions, configured to, when executed, to cause at least one processor to: capture an image of the host structure with the first embedded component; measure the gap between the well wall and the perimeter of the first embedded component; compare the measured gap to the predetermined gap threshold; compare the measured gap to the bridging threshold; if the measured gap is greater than the gap threshold yet smaller than the bridging threshold, instruct at least one of the operator and the additive manufacturing system to print a bridging member between the perimeter wall of the embedded component and the top surface of the host structure adjacent to the well wall; else if the measured gap is smaller than the gap threshold, prevent the additive manufacturing system from adding the bridging member between the perimeter wall of the embedded component and the top surface of the host structure adjacent to the well wall; else if the measured gap is greater than the gap threshold and greater than the bridging threshold, actuate an alarm.

As used herein, capturing an image of the host structure with the embedded components, refer to capturing at least one of an optical image, an acoustic footprint, and proximity profile (e.g., using atomic force microscopy or a robotic proximity sensing). In other words, sensing means that provide a snapshot of the current state of the embedded components in the host structure.

In general, in one embodiment, the optical module comprises machine vision module. Basic machine vision systems used in the systems and methods provided herein can comprise one or more cameras (typically having solid-state charge couple device (CCD) imaging elements) directed at an area of interest, frame grabber/image processing elements that capture and transmit CCD images, a computer and optionally a display for running the machine vision software application and manipulating the captured images, and appropriate illumination on the area of interest.

The use of the term “module” does not imply that the components or functionality described or claimed as part of the module are all configured in a (single) common package. Indeed, any or all of the various components of a module, whether control logic or other components, can be combined in a single package or separately maintained and can further be distributed in multiple groupings or packages or across multiple (remote) locations and devices.

In addition, the computer program, can comprise program code means for carrying out the steps of the methods described herein, as well as a computer program product comprising program code means stored on a medium that can be read by a computer, such as a hard disk, CD-ROM, DVD, USB memory stick, or a storage medium that can be accessed via a data network, such as the Internet or Intranet, when the computer program product is loaded in the main memory of a computer and is carried out by the computer.

Memory device(s) as used in the methods described herein can be any of various types of non-volatile memory devices or storage devices (in other words, memory devices that do not lose the information thereon in the absence of power). The term “memory device” is intended to encompass an installation medium, e.g., a CD-ROM, or tape device or a non-volatile memory such as a magnetic media, e.g., a hard drive, optical storage, or ROM, EPROM, FLASH, etc. The memory device may comprise other types of memory as well, or combinations thereof. In addition, the memory medium may be located in a first computer in which the programs are executed (e.g., the additive manufacturing system), and/or may be located in a second different computer which connects to the first computer over a network, such as the Internet. In the latter instance, the second computer may further provide program instructions to the first computer for execution. The term “memory device” can also include two or more memory devices which may reside in different locations, e.g., in different computers that are connected over a network. Accordingly, for example, the bitmap library can reside on a memory device that is remote from the CAM module coupled to the additive manufacturing system provided, and be accessible by the additive manufacturing system provided (for example, by a wide area network).

Unless specifically stated otherwise, as apparent from the following discussions, it is appreciated that throughout the specification discussions utilizing terms such as “processing,” “loading,” “in communication,” “detecting,” “calculating,” “determining”, “analyzing,” or the like, refer to the action and/or processes done either manually, or by a computer or computing system, or similar electronic computing device, that manipulate and/or transform data represented as physical, such as a transistor architecture into other data similarly represented as physical structural (in other words, relative location coordinates within the well).

The Computer-Aided Design/Computer-Aided Manufacturing (CAD/CAM) generated information associated with the host structure comprising the embedded components described herein to be fabricated, which is used in the methods, programs and libraries can be based on converted CAD/CAM data packages can be, for example, IGES, DXF, DWG, DMIS, NC files, GERBER® files, EXCELLON®, STL, EPRT files, an ODB, an ODB++, an.asm, an STL, an IGES, a STEP, a Catia, a SolidWorks, a Autocad, a ProE, a 3D Studio, a Gerber, a Rhino a Altium, an Orcad, an Eagle file or a package comprising one or more of the foregoing. Additionally, attributes attached to the graphics objects transfer the meta-information needed for fabrication and can precisely define the printed circuit boards including embedded chip components described herein image and the structure and color of the image (e.g., resin or metal), resulting in an efficient and effective transfer of fabrication data from design (3D visualization CAD e.g.,) to fabrication (CAM e.g.,). Accordingly and in an embodiment, using pre-processing algorithm, GERBER®, EXCELLON®, DWG, DXF, STL, EPRT ASM, and the like as described herein, are converted to 2D files.

A more complete understanding of the components, processes, assemblies, and devices disclosed herein can be obtained by reference to the accompanying drawings. These figures (also referred to herein as “FIGS.”) are merely schematic representations (e.g., illustrations) based on convenience and the ease of demonstrating the present disclosure, and are, therefore, not intended to indicate relative size and dimensions of the devices or components thereof and/or to define or limit the scope of the exemplary embodiments. Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

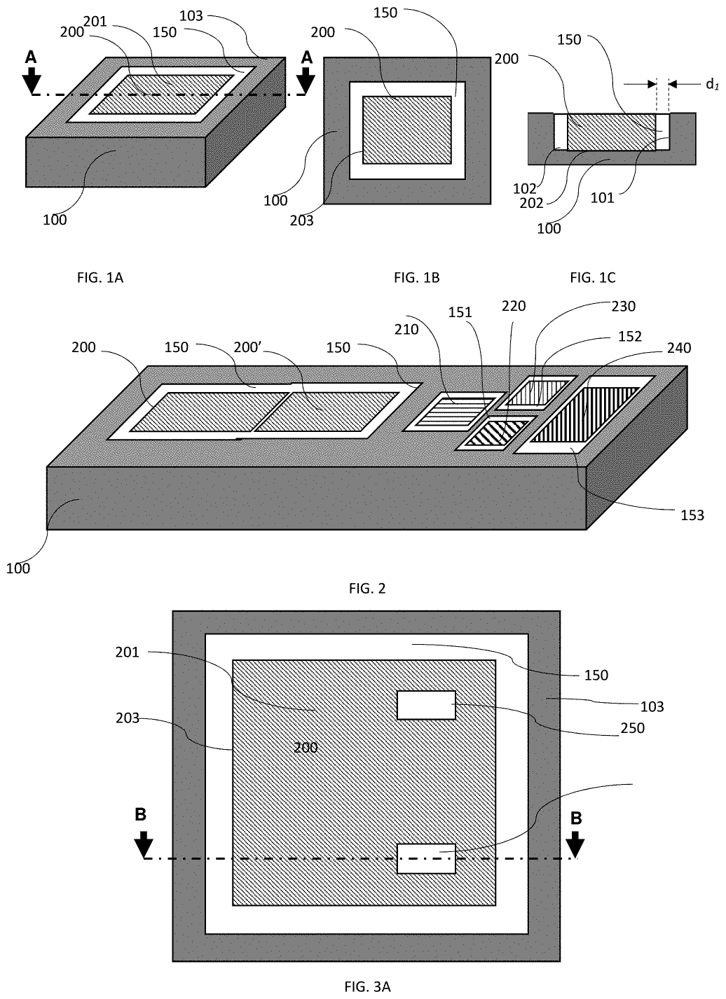

Turning now to FIG. 1, illustrating a perspective (1A), top (1B), and cross-sectional view (1C) of a schematic example of host structure 100, and embedded component 200. Host structure 100 could be manufactured by standard manufacturing processes or using additive manufacturing techniques while the embedded component 200 is produced in a separate equipment and then placed inside well 150 manually or by automated pick-and-place equipment (e.g., robot arm module). Due to natural manufacturing tolerances for both host structure and embedded component 200, there is always a gap “d₁” between well wall 101 and adjacent top surface 103 and the perimeter 203 of the embedded components 200. The design and manufacturing of host structure 100 make well 150 where the embedded component is to be placed as narrow as possible to enable the pick and place, receiving and accommodating the first and second or more components 200. Accordingly, gap “d₁” can be anything between 1 μm to 1000 μm, for example, between 10 μm and 500 μm. FIG., 2 shows also host structure 100 where a plurality of different embedded components or mechanical, acoustical, thermal, or optical components are located inside host structure 100 well 150, with some sharing an adjacent space between them (e.g., 200, 200′). Here too, gaps are present between all the structures because of the inherent host structure and component manufacturing tolerances, and pick and place needs.

In many instances the embedded device or component 200 could have areas for functional connections such as contact pads 250, 251 (see e.g., FIG. 3A) for electronic devices, sensors, transducers, thermal, or optical carrying input and output signals. It may be desirable to place corresponding connecting material such as traces 301, 302 (see e.g., FIG. 3C) between the contact pads 250, 251 in the embedded device (e.g., component 200) and adjacent top surface 103 of the of host structure 100 from where it will be further connected depending on the final assembly of the composite structure as shown in FIG. 3C, 3D. When typical additive manufacturing is used for depositing traces 301, 302, the dimension of gap “d₁” between well wall 101 and embedded component 200 perimeter 203, or between one embedded component 200 to another 200′ as illustrated in FIG. 2, the resulting gap d₁ plays an important role in the integrity and functionality of the finished product. The viscosity of the material forming traces 301, 302 and the deposition method can also play an important role. Consequently, traces 301, 302 could end up disconnected, which can be caused by the gap (see e.g., FIG. 3D), or with a narrowing of the interconnect material (traces 301, 302) over gap “d”. While ostensibly providing some functionality, this narrowing of traces 301, 302 is known by skilled artisans in the field of electronic devices, to limit the reliability of the assembled structure.

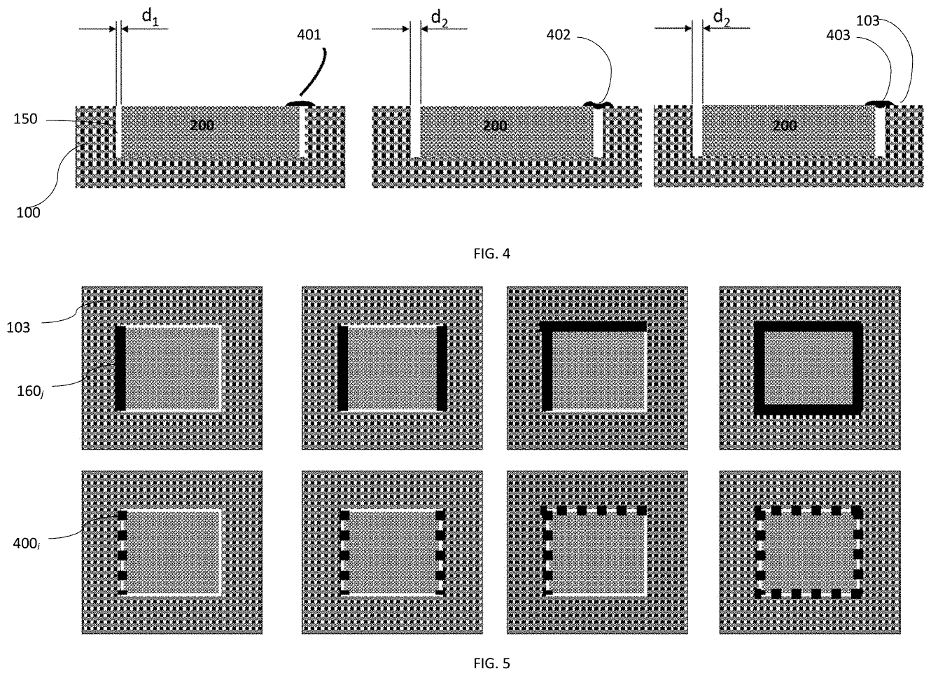

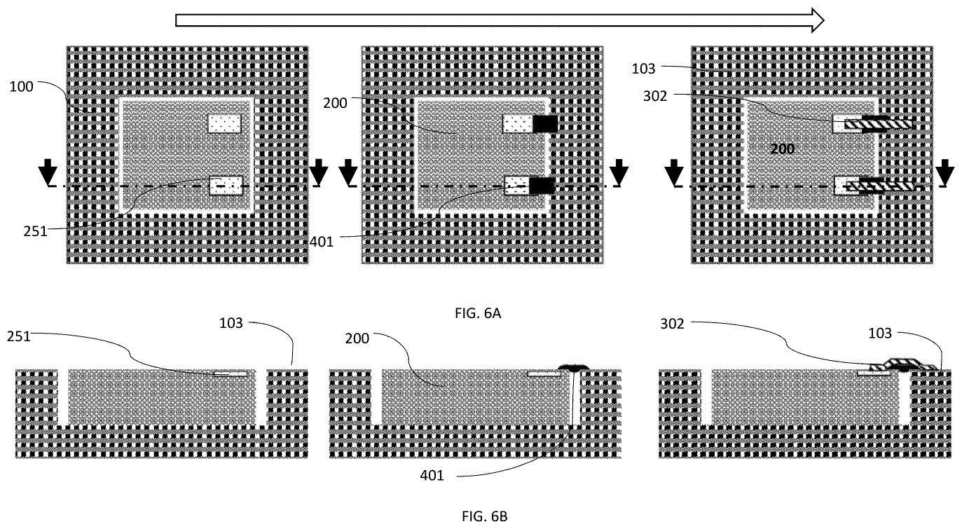

The disclosed technology provides for a bridging member 401 (see e.g., FIG. 4, left) to be deposited above gap d₁ between host structure 100 and embedded component (e.g., IC 200) or between different embedded component (e.g., IC 200, 210, 220 etc. See e.g., FIG. 2) in order to overcome limitations that such a gap presents when interconnecting traces is/are necessary, as shown in FIG. 3D Furthermore, as gap d₁ increases, gap d₂ is larger than gap d₁, bridging member 402 sags while transitioning between well wall 101 and the perimeter of the component 203. Using additive manufacturing could further enable to fill this dip (caused by sagging), hence producing an almost straight bridging member 403 if necessary. In FIG. 4 bridging member(s) 401 (403) could also be used as a mechanical reinforcing structure to ensure that embedded component is fixed in place. The size of bridging member 401 can be selected based on specific integration needs of final product between host structure 100 and embedded component. It could be single sided all way to four sides, as well as sectional as shown in FIG. 5 where it applies only in the sections where connectivity is desired. Using bridging member 400ᵢ allows for a reliable placement by additive manufacturing of traces 301, 302 between top surface of the host structure adjacent to the well wall 103 and perimeter 203 of embedded component 200, as shown in FIG. 6.

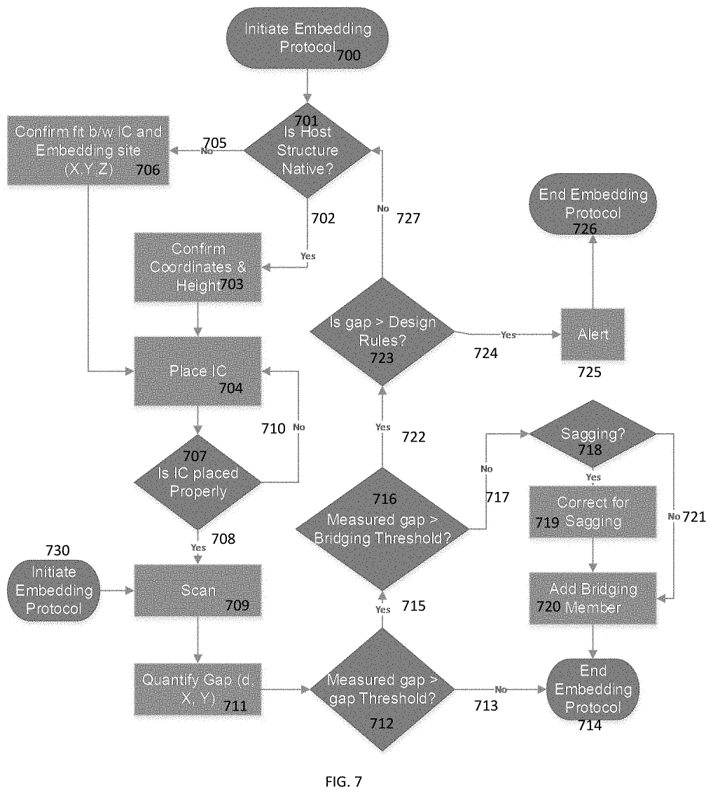

FIG. 7 shows a typical flow chart for the logic used by processor of computer to control process. In order to accurately place bridging member 401, scanning 709 can be carried out via machine vision e.g., using optical, acoustics, electrostatic, or mechanical means to determine dimensions of host structure 100 well 150 as well as the location of well 150 on additive manufacturing equipment. Embedded component 200 can be placed 704 manually or automatically by a pick and place automated system. In an embodiment, computer is used to manage data acquisition and manage placement of components. The inspection module then scans structures to determine size of gap “d₁” 711. If this gap exceeds predefined design rules 720, the process is stopped and system operator is alerted 722 for intervention or part is placed in a rejected parts bin. Otherwise 715, based on gap size, bridging member 401 properties, and device design bridge member 401 is placed 718 and apical surface 201 and further, made flat if necessary.

Accordingly and in an embodiment as illustrated in FIGS. 1-7, provided herein is a method for increasing connectivity of integrated circuits 200 in host structure 100 implementable in an additive manufacturing adder comprising: providing host structure 100 with top surface 103 comprising well 150 having well wall 101 and well floor 102 configured to receive and accommodate first component to be embedded 200; positioning first component 200 having apical surface 201, basal surface 202 and perimeter 203 within well 150, thereby embedding first component 200; inspecting first embedded component 200; determining gap dₙ between well wall 101 and perimeter 203 of first embedded component 200: and if gap dₙ between well wall 101 and perimeter 203 of embedded component 200 is above a predetermined gap threshold TH_{G} yet smaller than a bridging threshold TH_{B}, using 3D printer or other additive manufacturing means, adding bridging member 400ᵢ between perimeter 203 of embedded component 200 and top surface 103 of the host structure 100 adjacent to well wall 101.

Apical surface 201 of component 200 can further comprises contact pads 250, 251, configured to electronically communicate, or transfer signal such as optical or acoustic signals with at least host structure 100 and a second component 200′, 210 e.g. Moreover, perimeter 203 of component 200 can be a polygon having three or more facets each having an apical surface 201. A quadrilateral polygon is illustrated in FIG. 5, but should not be limiting. It is noted that the step of adding bridging member 401 between perimeter 203 of first or second or other embedded component 200 e.g., and top surface 103 of the host structure 100 adjacent to well wall 101 can be preceded by a step of determining gap dₙ between well wall 101 and each facet of perimeter 203 (in case of a polygon) of first embedded component 200, then adding bridging member 401 between perimeter wall 203 of embedded component 200 and top surface 103 of the host structure 100 adjacent to well wall 101. As illustrated in FIGS. 6A, 6B bridging member 401 can be added between a portion of contact pad 251 and top surface 103 of the host structure 100 adjacent to well wall 101, which can be followed by adding either a conductive trace 302 between another portion of contact pad 251, or an insulating and/or dielectric trace 302, and at least one of top surface 103 of host structure 100 and/or second component 200′ (see e.g., FIG. 2), over bridge member 401. Any artisan skilled in the art can conclude that other materials can be added for providing path for thermal, light, and acoustic conductivity.

In an embodiment, the additive manufacturing printer used to fabricate the structures with improved mechanical, optical, thermal, acoustic and electrical connectivity further comprises: a processing chamber: a processing chamber; at least one of an optical module, a mechanical module, and an acoustic module; wherein the at least one of optical module, mechanical module, and the acoustic module comprise a processor in communication with a non-volatile memory including a processor-readable media having thereon a set of executable instructions, configured to, when executed, cause processor to: capture an image of host structure 100 with first embedded component 200; measure gap d between well wall 101 and perimeter 203 of first embedded component 200; compare measured gap d to predetermined gap threshold TH_{G}; compare measured gap d to bridging threshold TH_{B}; if measured gap d is greater than gap threshold TH_{G} yet smaller than bridging threshold TH_{B} (TH_{B}>d>TH_{G}), instruct the operator and/or the additive manufacture system (in other words, automatically), to add bridging member 401 between perimeter wall 203 of embedded component 200 and top surface 103 of the host structure 100 adjacent to well wall 101; else if measured gap d is smaller than gap threshold TH_{G} (d<TH_{G}), prevent printer from adding bridging member 401; else if measured gap d is greater than gap threshold TH_{G} and greater than bridging threshold TH_{G}, (d>TH_{B}), actuate an alarm.

An embodiment of the method is illustrated in FIG. 7, as illustrated upon initiating embedding protocol 700, host structure is scanned to determine whether is native 701 and if so 702 well 150 coordinates, and depth of floor 102 are compared to the parameters of the yet-to-be-embedded component and confirmed 703 at which point component 200 is placed 704 either manually or automatically within well 150. If host structure is not native 705, the system will confirm the fit between embedding site well 150 and the yet-to-be-embedded component 200, then placed 704 within well 150 thus embedding component 200. The system will then determine 707 if component 200 is properly placed within well 150 and if so 708 will initiate scan 709 of the embedded component 200 (with mechanical and/or optical, and/or acoustical e.g.,), or if not placed properly 710, will be placed again 704. Following the scan, the optical module and/or mechanical module, and/or acoustical module, and the inspection algorithm will quantify 711 (in other words measure) gap d between well wall 101 and component 200 perimeter 203 and between any facet of perimeter 203 and adjacent top surface 103 of the host structure 100 adjacent to well wall 101, then the algorithm will analyze if 713 measured gap d is larger than TH_{G}, and if not 713, prevent 714 the adding of bridging member 401. If on the other hand measured gap d is larger 715 than TH_{G}, the system will analyze if 716 measured gap d is larger than bridging threshold TH_{B}, and if not 717, the system queries 718 whether, based on, for example measured gap d₂ (FIG. 4, center) and the bridging material, would the bridging result in sagging, if so, the additive manufacturing system (or any operator outside the system) will correct 719 for the sagging (see e.g., FIG. 6B, center), add 720 bridging member 401 and terminate 714 the embedding protocol for that component 200. On the other hand, if no sagging 721 is expected, the additive manufacturing system (or any operator outside the system) will add 720 bridging member 401 and terminate 714 the embedding protocol for that component 200. Otherwise, if measured gap d is 722 larger than bridging threshold TH_{B}, the system will review 723 the measured gap d in light of the design rule(s) for the completed structure and if the measured gap d is not within the constraints of the design rule 724, alert 725 the operator and stop the addition. If, however, the gap is 727 within the design rules the system will again determine 701 whether host structure 100 is native to the yet-to-be-embedded component 200 and repeat the process.

It is also contemplated that using the methods provided herein, the protocol can be initiated 725 on already embedded component(s) that have not been subject to the initial stages (steps 700-707).

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

All ranges disclosed herein are inclusive of the endpoints, and the endpoints are independently combinable with each other. “Combination” is inclusive of blends, mixtures, alloys, reaction products, and the like. The terms “a”, “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the component(s) includes one or more component). Reference throughout the specification to “one embodiment”, “another embodiment”, “an embodiment”, and so forth, when present, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments. Furthermore, the terms “first,” “second,” and the like, herein do not denote any order, quantity, or importance, but rather are used to denote one element from another.

Likewise, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

Accordingly and in an embodiment, provided herein is a method for increasing connectivity of embedded components in a host structure implementable in an additive manufacturing system comprising: providing the host structure with a top surface comprising a well having a well wall and a well floor configured to receive and accommodate a first component to be embedded; positioning the embedded component having an apical surface, a basal surface and a perimeter within the well, thereby embedding the first component; inspecting the first embedded component; determining the gap between the well wall and the perimeter of the first embedded component: and if the gap between the well wall and the perimeter of the embedded component is above a predetermined gap threshold yet smaller than a bridging threshold, using the additive manufacturing system, adding a bridging member between the perimeter wall of the embedded component and the top surface of the host structure adjacent to the well wall, wherein (i) the apical surface of the first embedded component further comprises contact pads, configured to communicate signals with at least the host structure and a second embedded component, (ii) the perimeter of the embedded component is a polygon having three or more facets, wherein (iii) the step of adding a bridging member between the perimeter of the embedded component and the top surface of the host structure adjacent to the well wall is preceded by a step of determining the gap between the well wall and each facet of the perimeter of the first embedded component, the method (iv) adding the bridging member on selectable top surface of each of the facets of the first embedded component, and (v) further comprising adding a bridging member between the perimeter of the embedded component and the top surface of the host structure adjacent to the well wall, (vi) the bridging member is added between a portion of the contact pad and the top surface of the host structure adjacent to the well wall, the method further comprising (vii) adding a signal conductive trace between another portion of the contact pad and at least one of the host structure and the second embedded component, over the bridge member, wherein (viii) the host structure is at least one of a printed circuit board, a flexible printed circuit, and a high-density interconnect printed circuit, (ix) at least the first embedded component and the second embedded component is a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, a Land Grid Array (LGA) package, a passive component, or a combination comprising the foregoing, wherein (x) the step of positioning is automated, wherein (xi) the additive manufacturing system further comprises: a processing chamber; and at least one of an optical module, a mechanical module, and an acoustic module; a camera, wherein the at least one of optical module, mechanical module, and the acoustic module comprise a processor in communication with a non-volatile memory including a processor-readable media having thereon a set of executable instructions, configured to, when executed, cause the processor to: capture an image of the host structure with the first embedded component; measure the gap between the well wall and the perimeter of the first embedded component; compare the measured gap to the predetermined gap threshold; compare the measured gap to the bridging threshold; compare the measured gap to a predetermined sagging threshold if the measured gap is greater than the gap threshold yet smaller than the sagging threshold, instruct at least one of the operator and the additive manufacturing system to add a bridging member between the perimeter of the embedded component and the top surface of the host structure adjacent to the well wall; else if the measured gap is greater than the gap threshold and greater than the sagging threshold yet smaller than the bridging threshold, instruct at least one of the operator and the additive manufacturing system to add a bridging member between the perimeter of the embedded component and the top surface of the host structure adjacent to the well wall and correct for the sagging; else if the measured gap is smaller than the gap threshold, prevent the additive manufacturing system from adding the bridging member between the perimeter of the embedded component and the top surface of the host structure adjacent to the well wall; else if the measured gap is greater than the gap threshold and greater than the bridging threshold, actuate an alarm, (xii) the bridging threshold gap is configured to prevent sagging of the bridging member, wherein (xiii) the bridging member forms a continuous layer between the embedded component's perimeter and the top surface of the host structure adjacent to the well wall, the method further comprising (xiv) adding at least one of: an insulating layer, a dielectric layer, an acoustic signal conveyor, a thermal transducer, and an electric conductor between the first embedded component perimeter and at least one of the host structure and a second embedded component, over the bridge member, wherein (xv) the additive manufacturing system further comprises an optical, acoustic, or mechanical device configured to detect the gap between the perimeter of the first embedded component and the well wall, wherein (xvi) the step of adding the bridging member is carried out manually, not using the additive manufacturing system, and wherein (xvii) correcting for the sagging comprises adding material configured to level the bridging member.

In another embodiment, provided herein is a processor readable media having thereon a set of executable instructions, configured to, when executed, cause a processor to: capture an image of a host structure comprising a well having a well wall and a well floor configured to receive and accommodate a first component to be embedded, wherein the first component has an apical surface, a basal surface and a perimeter; using at least one of an optical module, and acoustic module, and a mechanical module, measure a gap between the well wall and the perimeter of the first embedded component; compare the measured gap to a predetermined gap threshold; compare the measured gap to a bridging threshold; if the measured gap is greater than the gap threshold and smaller than the bridging threshold, instruct at least one of the operator and the additive manufacturing system to print a bridging member between the perimeter of the embedded component and the top surface of the host structure adjacent to the well wall; else if the measured gap is smaller than the gap threshold, prevent the additive manufacturing system from adding a bridging member between the perimeter of the embedded component and the top surface of the host structure adjacent to the well wall; else if the measured gap is greater than the gap threshold and greater than the bridging threshold, actuate an alarm.

Although the foregoing disclosure for using additive manufacturing to improve connectivity of embedded components to the host structure has been described in terms of some embodiments, other embodiments will be apparent to those of ordinary skill in the art from the disclosure herein. Moreover, the described embodiments have been presented by way of example only, and are not intended to limit the scope of the inventions. Indeed, the novel methods, programs, libraries and systems described herein may be embodied in a variety of other forms without departing from the spirit thereof. Accordingly, other combinations, omissions, substitutions and modifications will be apparent to the skilled artisan in view of the disclosure herein.

1. A method for increasing connectivity of embedded components in a host structure implementable in an additive manufacturing system comprising:
a. providing the host structure with a top surface comprising a well having a well wall and a well floor configured to receive and accommodate a first component to be embedded;
b. positioning the embedded component having an apical surface, a basal surface and a perimeter within the well, thereby embedding the first component;
c. inspecting the first embedded component;
d. determining the gap between the well wall and the perimeter of the first embedded component: and
e. if the gap between the well wall and the perimeter of the embedded component is above a predetermined gap threshold yet smaller than a bridging threshold, using the additive manufacturing system, adding a bridging member between the perimeter wall of the embedded component and the top surface of the host structure adjacent to the well wall.

2. The Method of claim 1, wherein the apical surface of the first embedded component further comprises contact pads, configured to communicate signals with at least the host structure and a second embedded component.

3. The Method of claim 2, wherein the perimeter of the embedded component is a polygon having three or more facets.

4. The Method of claim 3, wherein the step of adding a bridging member between the perimeter of the embedded component and the top surface of the host structure adjacent to the well wall is preceded by a step of determining the gap between the well wall and each facet of the perimeter of the first embedded component.

5. The Method of claim 3 further comprising adding a bridging member between the perimeter of the embedded component and the top surface of the host structure adjacent to the well wall.

6. The Method of claim 5, wherein the bridging member is added between a portion of the contact pad and the top surface of the host structure adjacent to the well wall.

7. The Method of claim 6, further comprising adding a signal conductive trace between another portion of the contact pad and at least one of the host structure and the second embedded component, over the bridge member.

8. The Method of claim 1, wherein the host structure is at least one of a printed circuit board, a flexible printed circuit, and a high-density interconnect printed circuit.

9. The Method of claim 1, wherein at least the first embedded component and the second embedded component is a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, a Land Grid Array (LGA) package, a passive component, or a combination comprising the foregoing.

10. The Method of claim 1, wherein the step of positioning is automated.

11. The Method of claim 1, wherein the additive manufacturing system further comprises:
a. a processing chamber; and
b. at least one of an optical module, a mechanical module, and an acoustic module,
c. a camera, wherein the at least one of optical module, mechanical module, and the acoustic module comprise a processor in communication with a non-volatile memory including a processor-readable media having thereon a set of executable instructions, configured to, when executed, cause the processor to:
i. capture an image of the host structure with the first embedded component;
ii. measure the gap between the well wall and the perimeter of the first embedded component;
iii. compare the measured gap to the predetermined gap threshold;
iv. compare the measured gap to the bridging threshold;
v. compare the measured gap to a predetermined sagging threshold
vi. if the measured gap is greater than the gap threshold yet smaller than the sagging threshold, instruct at least one of the operator and the additive manufacturing system to add a bridging member between the perimeter of the embedded component and the top surface of the host structure adjacent to the well wall; else
vii. if the measured gap is greater than the gap threshold and greater than the sagging threshold yet smaller than the bridging threshold, instruct at least one of the operator and the additive manufacturing system to add a bridging member between the perimeter of the embedded component and the top surface of the host structure adjacent to the well wall and correct for the sagging; else
viii. if the measured gap is smaller than the gap threshold, prevent the additive manufacturing system from adding the bridging member between the perimeter of the embedded component and the top surface of the host structure adjacent to the well wall; else
ix. if the measured gap is greater than the gap threshold and greater than the bridging threshold, actuate an alarm.

12. The Method of claim 11, wherein the bridging threshold gap is configured to prevent sagging of the bridging member.

13. The Method of claim 1, wherein the bridging member forms a continuous layer between the embedded component's perimeter and the top surface of the host structure adjacent to the well wall.

14. The Method of claim 3, comprising adding the bridging member on selectable top surface of each of the facets of the first embedded component.

15. The Method of claim 1, further comprising adding at least one of an insulating layer, a dielectric layer, an acoustic signal conveyor, a thermal transducer, and an electric conductor between the first embedded component perimeter and at least one of the host structure and a second embedded component, over the bridge member.

16. The Method of claim 1, wherein the additive manufacturing system further comprises an optical, acoustic, or mechanical device configured to detect the gap between the perimeter of the first embedded component and the well wall.

17. The Method of claim 5, wherein the step of adding the bridging member is carried out manually, not using the additive manufacturing system.

18. The Method of claim 11, wherein correcting for the sagging comprises adding material configured to level the bridging member.

19. A processor readable media having thereon a set of executable instructions, configured to, when executed, cause a processor to:
i. capture an image of a host structure comprising a well having a well wall and a well floor configured to receive and accommodate a first component to be embedded, wherein the first component has an apical surface, a basal surface and a perimeter;
ii. using at least one of an optical module, and acoustic module, and a mechanical module, measure a gap between the well wall and the perimeter of the first embedded component;
iii. compare the measured gap to a predetermined gap threshold;
iv. compare the measured gap to a bridging threshold;
v. if the measured gap is greater than the gap threshold and smaller than the bridging threshold, instruct at least one of the operator and the additive manufacturing system to print a bridging member between the perimeter of the embedded component and the top surface of the host structure adjacent to the well wall; else
vi. if the measured gap is smaller than the gap threshold, prevent the additive manufacturing system from adding a bridging member between the perimeter of the embedded component and the top surface of the host structure adjacent to the well wall; else
vii. if the measured gap is greater than the gap threshold and greater than the bridging threshold, actuate an alarm.
